(19) United States
(12) Patent Application Publication
(10) Pub. No.: US 2019/0212171 A1
(43) Pub. Date: Jul. 11, 2019

(54) INDUCTIVE SENSOR WITH DIGITAL DEMODULATION

(71) Applicant: Raytheon Company, Waltham, MA (US)

(72) Inventor: John J. Anagnost, Torrance, CA (US)

(21) Appl. No.: 15/864,097

(22) Filed: Jan. 8, 2018

(51) Int. Cl. G01D 5/20; G01R 19/252

(52) U.S. Cl. CPC G01D 5/20; G01R 19/252

(57) ABSTRACT

An eddy current displacement sensor includes devices or modules for digitizing and interpreting analog signals received from sensor coils. Periodic analog signals, such as sinusoidal or square wave signals, are sent to the coils with a suitable frequency. The output from the coils is then digitized using one or more analog-to-digital converters, at a sampling rate (frequency) that may be greater than that of the frequency of the input signal. The digitized output signals may then be processed to determine displacement of an object relative to the sensor coils, for example using magnitude and/or phase of the digital signals to estimate position. Digitizing the analog output signals directly, rather than only after such signals have been converted to DC signals, allows improvement in processing, as well as enabling flexibility in how the signals are used to estimate position.

### FIELD OF THE INVENTION

The invention is in the field of inductive sensors, such as eddy current displacement sensors.

### DESCRIPTION OF THE RELATED ART

In eddy current displacement sensors, analog drive circuits are used to provide an oscillating magnetic field to sensor coils (heads), which are parts of a sensor network. The drive circuits provide an oscillating magnetic field to drive the sensor coils, with a frequency of about 500 kHz. The sensor network detects changes in the sensor head impedance due to the proximity of a target to the sensor head. These impedance changes are proportional to distance from target to sensor heads. The output of the sensor network is a sinusoid that must be demodulated to determine amplitude and/or phase from which position can be determined. Various demodulation circuits have been employed.

### SUMMARY OF THE INVENTION

An inductive sensor digitizes output signals prior to digital demodulation.

According to an aspect of the invention, an inductive sensor includes: a pair of sensor heads; one or more current drives that apply periodic current to the heads at a drive frequency; one or more analog-to-digital converters that receive analog output signals from the sensor heads and convert the analog output signals to digital signals; and a digital demodulator that receives the digital signals from the one or more analog-to-digital converters, and determines phase and/or amplitude of the digital signal, with the phase and/or the amplitude of the digital signals used to determine displacement of an item between the sensor heads.

According to an embodiment of any paragraph(s) of this summary, the sensor further includes a pair of resonating capacitors, with the resonating capacitors in parallel with respective of the sensor heads.

According to an embodiment of any paragraph(s) of this summary, the sensor further includes a position estimator in the processor or firmware that uses the phase and/or the amplitude of the digital signals as and input, and determines the displacement of the item between the sensor heads.

According to an embodiment of any paragraph(s) of this summary, the position estimator may also use external calibration data as an input, in addition to the phase and/or the amplitude.

According to an embodiment of any paragraph(s) of this summary, the one or more current drives includes separate current drives corresponding to respective of the sensor heads.

According to an embodiment of any paragraph(s) of this summary, the one or more analog-to-digital converters includes separate analog-to-digital converters corresponding to respective of the sensor heads.

According to an embodiment of any paragraph(s) of this summary, the digital demodulator uses a Fourier transform to demodulate the digital signals.

According to an embodiment of any paragraph(s) of this summary, the digital demodulator uses an aliasing algorithm to demodulate the digital signals.

According to an embodiment of any paragraph(s) of this summary, the digital demodulator is part of a processor or field programmable gate array (FPGA).

According to an embodiment of any paragraph(s) of this summary, the one or more current drive receives one or more signals from one or more digital-to-analog converters that have a conversion rate that is an integer multiple of a frequency of a digital periodic input signal.

According to an embodiment of any paragraph(s) of this summary, a conversion rate of the one or more analog-to-digital converters is the conversion rate of one or more analog-to-digital converters, divided by an integer that is different from the integer multiple.

According to another aspect of the invention, a method of determining position of an object relative to sensor heads of an inductive sensor, includes the steps of: applying periodic current to the sensor heads at a drive frequency; digitizing output signals from the sensor heads to produce digitized output signals; and using phase and/or amplitude of the digitized output signals to determine position of the object relative to the sensor heads.

According to an embodiment of any paragraph(s) of this summary, the method further including using a digital-to-analog converter to produce the periodic current from a digital periodic input signal.

According to an embodiment of any paragraph(s) of this summary, the digital-to-analog converter converts the digital input signal at a conversion rate that is an integer multiple of a frequency of the digital periodic input signal.

According to an embodiment of any paragraph(s) of this summary, the digitizing includes digitizing in an analog-to-digital converter at a conversion rate that is the conversion rate of the analog-to-digital converter, divided by an integer that is different from the integer multiple.

According to an embodiment of any paragraph(s) of this summary, the digitizing includes digitizing in an analog-to-digital converter at a conversion rate that less that the conversion rate of the analog-to-digital converter.

According to an embodiment of any paragraph(s) of this summary, the using the phase and/or the amplitude of the digitized output signals also includes using calibration data.

According to an embodiment of any paragraph(s) of this summary, the method further including applying a Fourier transform on the digitized output signals to determine the phase and/or the amplitude of the digitized output signals.

According to an embodiment of any paragraph(s) of this summary, the method further including applying an aliasing algorithm on the digitized output signals to determine the phase and/or the amplitude of the digitized output signals.

To the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

The annexed drawings show various aspects of the invention.

FIG. 1 is a block diagram of an impedance sensor according to a first embodiment of the invention.

FIG. 2 is a block diagram of an impedance sensor according to a second embodiment of the invention.

FIG. 3 is a block diagram of an impedance sensor according to a third embodiment of the invention.

FIG. 4 is a block diagram of an impedance sensor according to a fourth embodiment of the invention.

FIG. 5 is a graph showing a sine wave and sampling points for an example use of an algorithm to demodulate sensor output.

FIG. 6 is a graph showing a sampled wave form corresponding to the example of FIG. 5.

FIG. 7 is a block diagram of an impedance sensor according to a fifth embodiment of the invention.

FIG. 8 is a high-level flow chart of a method of determining position of an object using an inductive sensor, according to an embodiment of the invention.

### DETAILED DESCRIPTION

An eddy current displacement sensor includes devices or modules for digitizing and interpreting analog signals received from sensor coils. Periodic analog signals, such as sinusoidal or square wave signals, are sent to the coils with a suitable frequency. The output from the coils is then digitized using one or more analog-to-digital converters, at a sampling rate (frequency) that may be greater than that of the frequency of the input signal, for example being a multiple of two (or more) times the input frequency. The digitized output signals may then be processed to determine displacement of an object relative to the sensor coils, for example using magnitude and/or phase of the digital signals to estimate position. The demodulation algorithm used to process the digitized signals may involve a Discrete Fourier Transform or an aliasing algorithm. Digitizing the analog output signals directly, rather than only after such signals have been converted to DC signals, allows improvement in processing, as well as enabling flexibility in how the signals are used to estimate position.

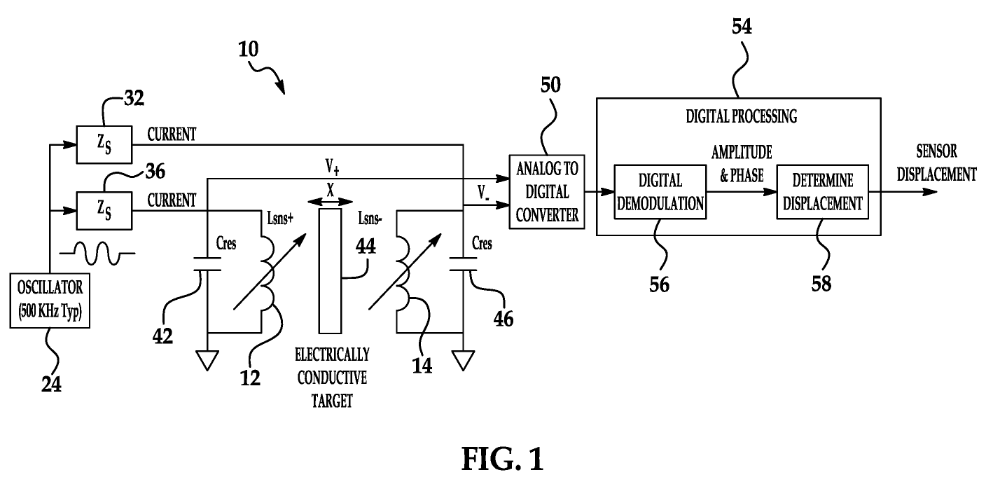

FIG. 1 shows a high-level view of an inductive sensor 10 or, more specifically, an eddy current displacement sensor for sensing position of an object, in this case the electrically conductive target 44. The sensor 10 includes a pair inductive sensor heads (sensors) 12 and 14 that receive analog periodic signals from oscillator 24. The signals may be at a suitable drive frequency, typically 100 kHz-2 MHz, and may be about 500 kHz.

Elements 32, and 36, labeled Zs in FIG. 1, are between the drive oscillator 24 and the ends of the corresponding sensor heads 12 and 14. The Zs elements 32 and 36 may be resistors, capacitors, inductors, or any combination thereof. Capacitors 42 and 46 are located between the sensor heads 12 and 14, and an analog-to-digital converter (ADC) 50 that processes output signals from the sensors 12 and 14. The capacitors 42 and 46 are chosen to resonate with the sensor heads 10 and 12 and to shunt a portion of the current from a resonant current produced by the sensor heads 12 and 14.

The ADC 50 converts the analog signal from the sensor heads 12 and 14 to a digital signal. This digital signal is then processed by a digital processor or digital processing module 54. The digital processing module 54 includes a digital demodulator 56 and a module 58 for determining displacement of an electrically-conductive body that is place between the sensors 12 and 14. The digital processor 54 demodulates the digitized output signal to determine a difference amplitude and/or phase difference between the signals at the sensors 12 and 14. This difference amplitude and/or phase difference can then be used to sensor head inductance 12 and 14. Knowledge of head inductance in turn can be used to estimate target position, using inductance alone or combined with other data (such as calibration data or a look-up table) to produce an output of the object displacement detected by the sensors 12 and 14. For example, current practice calibrates the sensor by moving the target position to known positions and comparing the sensor estimated target position to these known positions. The differences between the estimated position and known positions can then be used within the device to reduce estimated position error via lookup table or other polynomial fit or other means.

Determining the amplitude or phase of the sinusoidal signal is sufficient for estimating the differential displacement of the sensor. The amplitude or phase information determines the location on the resonance curve, and that location on the resonance curve corresponds to a unique displacement of the sensor. Other techniques such as transfer function estimation using Kalman filters, instrument variables, or state variables estimation (or other techniques) may provide even more accurate estimates of position at the expense of greater computer processing. In this approach, it is not assumed the resonance curve is fixed as in the simpler methods. Instead, the algorithms estimate the resonance curve that changes as a function of temperature of the components as well as the position of the target. This allows for more accurate determination of differential displacement than the simpler methods.

In operation, the periodic alternating drive signal on the sensor heads 12 and 14 produces an oscillating magnetic field. The magnetic field induces eddy currents in the object 44 that is between the sensor heads 12 and 14, creating an opposing magnetic field that resists the magnetic field generated by the sensor heads 12 and 14. The output signal from the sensor heads 12 and 14 is the input periodic drive signal, altered in phase and/or amplitude by the field interaction.

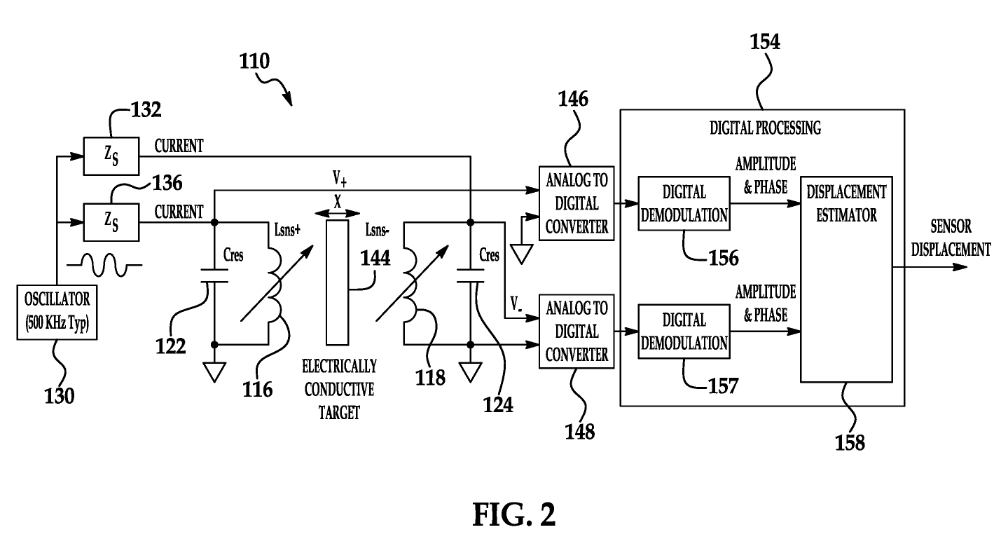

FIG. 2 shows a high-level view of an alternate embodiment eddy current displacement sensor 110, with sensor heads 116 and 118. The sensor heads 116 and 118 are illustrated as having respective capacitors 122 and 124. A current drive 130 produces a periodic signal, at a drive frequency, that is sent to both sensor heads 116 and 118. Respective Zs elements are between the sensor heads 116 and 118, and the current drive 130. The sensor heads 116 and 118 detect position of a conductive target 144.

A pair of ADCs 146 and 148 digitize the respective signals from the sensor heads 116 and 118. The digitized signals are then processed by a digital processing module 154 that includes a digital demodulators 156 and 157, and a module 158 for determining displacement of an electrically-conductive body that is place between the sensors 112 and 114.

The sensors 10 and 110 shown in FIGS. 1 and 2 offer flexibility and advantages over prior approaches. Analog demodulation can add noise and nonlinearity to a signal, running the risk of corrupting the signal from the sensor heads. Digitizing the signals before performing a digital demodulation avoids this problem.

In addition the digitization of the output upstream of the demodulation reduces the number of parts and cost of the sensor. More than half the parts of the eddy current displacement sensor may be omitted by digitizing upstream of the demodulator.

Furthermore, as described in greater detail below, the digitization of the signal allows increased flexibility in terms of how displacement is determined. Differences in amplitude and/or phase may be used in determining displacement.

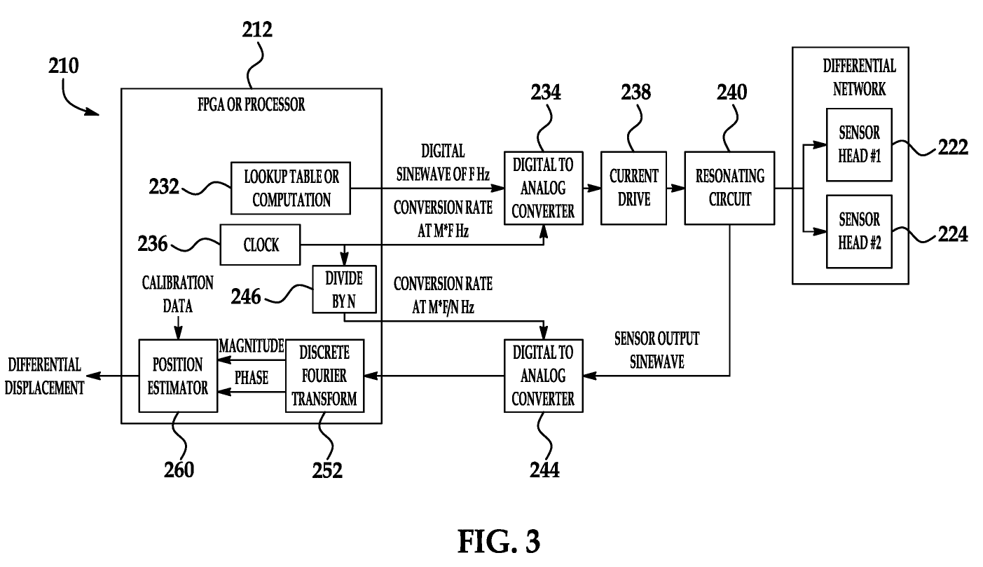

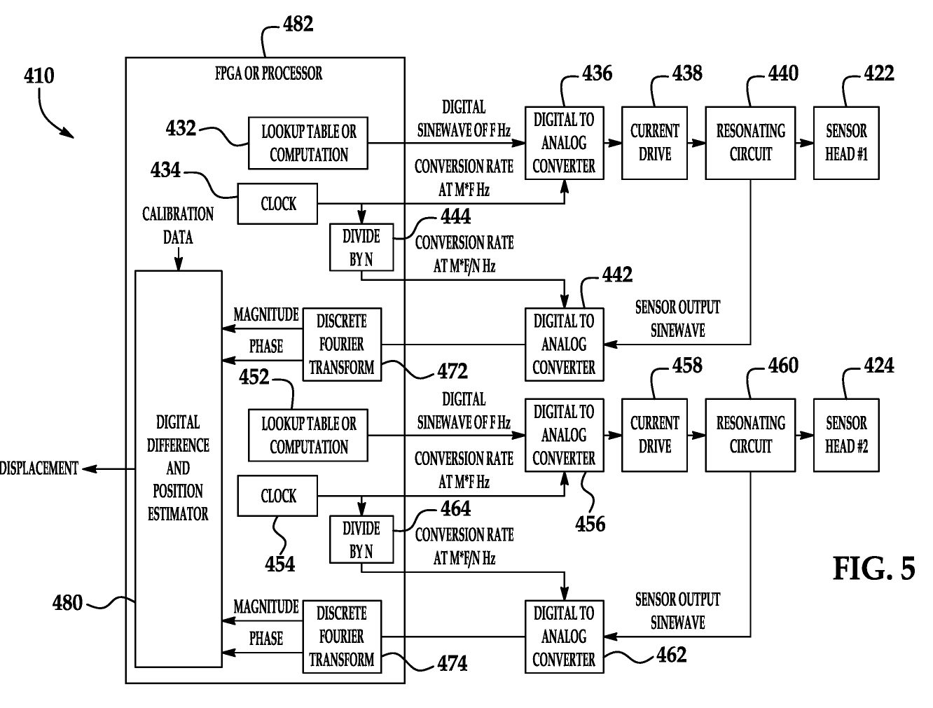

FIGS. 3-5 show further embodiments, with different arrangements for demodulation methods and/or circuits. Some of the details of the eddy current displacement sensors 10 and 110 (FIGS. 1 and 2, respectively) are part of at least some of the following embodiments, without being described in detail. It will be appreciated that some or all of the features of the various embodiments described herein can be combined in different combinations in a single embodiment, where appropriate.

FIG. 3 shows an eddy current displacement sensor 210 which has a field-programmable gate array (FPGA) or processor 212 that includes components that provide signals to sensor heads 222 and 224, and process signals received from the sensor heads 222 and 224. A sine wave (or other periodic signal) is created by a digital processor of the FPGA 212, for example according to a lookup table or by direct computation, as indicated in block 232. This digital sine wave is then turned into an analog signal by a digital-to-analog converter (DAC) 234. The conversion in the DAC 234 may be accomplished at a precise conversion rate that is an integer multiple of the frequency of the sine wave. The DAC conversion rate is controlled by a clock 236. For example, if the digital sine wave is 500 kHz, the conversion rate could be exactly 100 times larger, or 50 MHz. The resulting analog sine wave is driven into a precision current drive 238, such as an industry-standard Howland amplifier. The current output from the current drive 238 is injected into resonating circuitry 240, and from there into the sensor heads 222 and 224, configured in a differential network to excite a varying magnetic field in the sensor heads 222 and 224. The resonance circuitry is primarily a capacitor network that is chosen based on the sensor head inductance 222/224. It may also contain resistive elements in some embodiments.

The sensor output from the sensor heads 222 and 224 passes back through the resonating circuit 240, and is then injected into an analog-to-digital converter (ADC) 244. The ADC 244 may be precisely sampled at an integer multiple greater than twice the frequency of the digital sine wave driven by the Nyquist criterion (or Nyquist frequency). Continuing the example given above, a 500 kHz initial could be sampled at 5 MHz, which is exactly 10 times the 500 kHz signal and 1/10 of the conversion rate of the DAC 234. This sampling is represented by a block 246 of the FPGA 212. The resulting digitized signal is then digitally demodulated in the FPGA 212 using a discrete Fourier transform 252. This returns the magnitude and phase of the digitized signal. By sampling at an integer multiple of the drive signal, the corresponding discrete Fourier transform 252 will theoretically return the sine wave amplitude and phase without error (limited by electronics noise). The magnitude and phase are then used by the FPGA 212 in a position determination algorithm 260 that determines the best estimate of position using these inputs as well as calibration data from the sensor. This resulting position is the output of the sensor 210. The position estimator algorithm 260 may be part of a processor or may be in firmware.

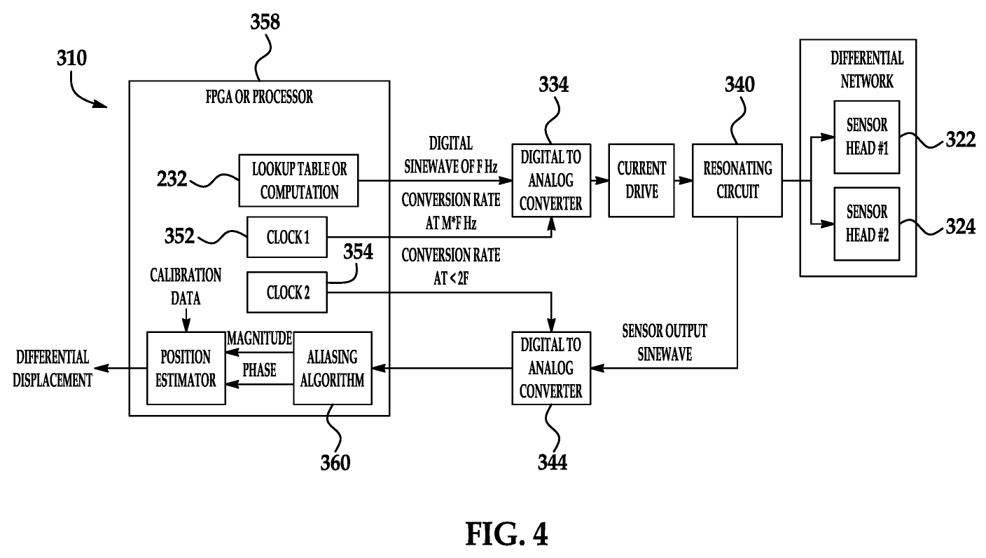

FIG. 4 shows a sensor 310 that is similar in many ways to the sensor 210 (FIG. 3). Many of the parts, such as sensor heads 322 and 324, a DAC 334, a resonating circuit 340, and an ADC 344, are similar to their counterparts in the sensor 210. However the sensor 310, in contrast to the sensor 210, intentionally samples the output signal at a frequency that is less than twice the rate at which the input sample is sampled. A first clock 352 directs the sampling performed by the DAC 334, and a second clock 354 directs the sampling performed by the ADC 344. The clocks 352 and 354 are both part of a processor or FPGA 358.

Digitized output from the ADC 344 is aliased by an aliasing algorithm 360 that is performed by the FPGA 358. The algorithm 360 can reconstruct the underlying sine wave from the aliased signal by relying on the known frequency of the sine wave which is driven by the FPGA 358.

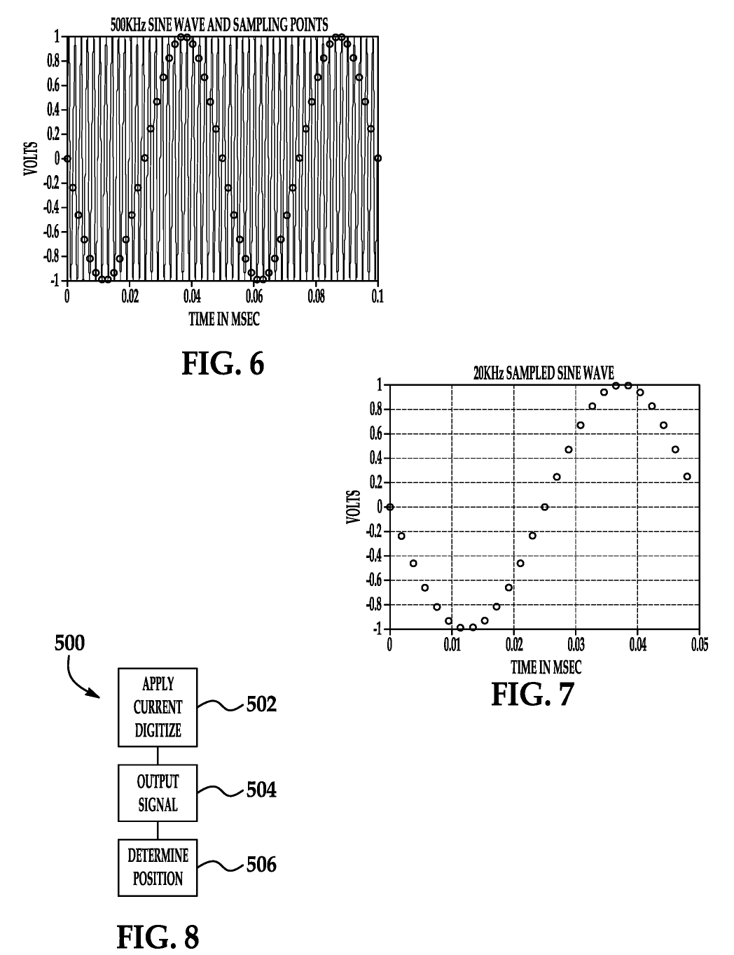

FIGS. 6 and 7 show some details on one embodiment of the algorithm 360 in reconstructing an underlying sine wave. In the example the sensor output is a 500 KHz, 1V amplitude sine wave, and is sampled at a 520 KHz rate. The 500 KHz sine wave and the sampling points are shown in FIG. 6. At this sampling rate 26 samples are accumulated in 50 μsec. The sampled wave form will alias to a 20 KHz, sine wave, as shown in FIG. 7.

Since the frequency of the sampled data is known, one can determine the amplitude and phase of this 50 μsec sample wave form by means of a linear, least squares fit algorithm, fitting the data using Equation (1):

f(t)=A+B sin(2π20000t)+C cos(2π20000t) (1)

This is first done by calculating a matrix M:

$$M = ( \begin{matrix}1 & sin ( 0 ) & cos ( 0 ) \\ 1 & sin ( 2 π20000 \times T ) & cos ( 2 π20000 \times T ) \\ 1 & sin ( 2 π20000 \times 2 T ) & cos ( 2 π20000 \times 2 T ) \\ ⋮ & ⋮ & ⋮ \\ 1 & sin ( 2 π2000 \times 26 T ) & cos ( 2 π20000 \times 26 T )\end{matrix} ) \qquad ( 2 )$$

The matrix M is then used to compute a pseudo-inverse matrix \tilde{M}:

\tilde{M}=(M^{T}M)⁻¹M^{T} (3)

This 26×3 matrix M can be computed ahead of time and stored in a look-up table.

Then a vector may be computed:

$$( \begin{matrix}A \\ B \\ C\end{matrix} ) = \tilde{M} ( \begin{matrix}{Y}_{1} \\ {Y}_{2} \\ ⋮ \\ {Y}_{26}\end{matrix} ) \qquad ( 4 )$$

where the symbol Yₙ is a sampled data point. These coefficients define a linear least-squares fit to the data in terms of an offset and the sine and cosine functions. The matrix multiply can be done in parallel. This would amount to 26 parallel multipliers, each doing 26 multiplications. The amplitude of the sine wave is \sqrt{B²+C²}. The phase is

$${tan}^{- 1} \frac{B}{C} .$$

FIG. 7 shows an eddy current displacement sensor 410 in which sensor heads 422 and 424 are driven separately. The sensor head 422 has a corresponding lookup table or computation block 432, clock 434, DAC 436, current drive 438, resonating circuit 440, ADC 442, and block 444 for setting the sampling speed of the DAC 436. The sensor head 424 has similar corresponding structures/features, a computation block 452, a clock 454, a DAC 456, a current drive 458, a resonating circuit 460, ADC 462, and a block 464 for setting the sampling speed of the DAC 456. The sensors 422 and 424 have their digitized signals demodulated using respective fast (discrete) Fourier transform modules 472 and 474, the output of which is used by a digital difference and position estimator 480, which is part of a FPGA or processor 482.

An advantage of the separate paths for the sensor heads 422 and 424 is that the balancing of the differential network in hardware requires testing of numerous precision components that make the buildup of the sensor electronics time consuming and variable from unit to unit. Furthermore, this two-head technique performs the differencing in the firmware or software rather than in the circuitry, preserving the information otherwise lost when the differencing is done in hardware. This may result in better system performance overall.

FIG. 8 shows a flow chart of a method 500 of determining position of an object relative to sensor heads of an inductive sensor that includes use of any of the eddy current displacement sensors described above. The method includes, in step 502, applying periodic current to the sensor heads at a drive frequency. This corresponds to items 24, 32 and 36 in the sensor 10 (FIG. 1); items 130, 132, and 136 in sensor 110 (FIG. 2); items 424, 432, 436, 488 in the sensor 410 (FIG. 7), items 234, 236 and 240 in the sensor 210 (FIG. 3); and items 352 and 334 in the sensor 310 (FIG. 4). Following that, in step 504 the inductive sensor digitizes output signals from the sensor heads to produce digitized output signals. This corresponds to item 50 in the sensor 10, items 146 and 148 in the sensor 110, items 244 and 246 in the sensor 210, and items 344 and 354 in the sensor 310. The digitized output is used in step 506 to determine position of an object, such as by using phase and/or amplitude of the digitized output signals to determine position of the object relative to the sensor heads. Both phase and amplitude may be used in determining the position. This corresponds to items 56 and 58 in the sensor 10, items 56, 156 and 158 in the sensor 110, items 252 and 260 in the sensor 210, and item 360 in the sensor 310.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

What is claimed is:

1. An inductive sensor comprising:
a pair of sensor heads;
one or more current drives that apply periodic current to the heads at a drive frequency;
one or more analog-to-digital converters that receive analog output signals from the sensor heads and convert the analog output signals to digital signals; and
a digital demodulator that receives the digital signals from the one or more analog-to-digital converters, and determines phase and/or amplitude of the digital signal, with the phase and/or the amplitude of the digital signals used to determine displacement of an item between the sensor heads.

2. The sensor of claim 1, further comprising a pair of resonating capacitors, with the resonating capacitors in parallel with respective of the sensor heads.

3. The sensor of claim 1, further comprising a position estimator in the processor or firmware that uses the phase and/or the amplitude of the digital signals as and input, and determines the displacement of the item between the sensor heads.

4. The sensor of claim 3, wherein the position estimator may also use external calibration data as an input, in addition to the phase and/or the amplitude.

5. The sensor of claim 1, wherein the one or more current drives includes separate current drives corresponding to respective of the sensor heads.

6. The sensor of claim 1, wherein the one or more analog-to-digital converters includes separate analog-to-digital converters corresponding to respective of the sensor heads.

7. The sensor of claim 1, wherein the digital demodulator uses a Fourier transform to demodulate the digital signals.

8. The sensor of claim 1, wherein the digital demodulator uses an aliasing algorithm to demodulate the digital signals.

9. The sensor of claim 1, wherein the digital demodulator is part of a processor or field programmable gate array (FPGA).

10. The sensor of claim 1, wherein the one or more current drive receives one or more signals from one or more digital-to-analog converters that have a conversion rate that is an integer multiple of a frequency of a digital periodic input signal.

11. The sensor of claim 10, wherein a conversion rate of the one or more analog-to-digital converters is the conversion rate of one or more analog-to-digital converters, divided by an integer that is different from the integer multiple.

12. A method of determining position of an object relative to sensor heads of an inductive sensor, the method comprising:
applying periodic current to the sensor heads at a drive frequency;
digitizing output signals from the sensor heads to produce digitized output signals; and
using phase and/or amplitude of the digitized output signals to determine position of the object relative to the sensor heads.

13. The method of claim 12, further comprising using a digital-to-analog converter to produce the periodic current from a digital periodic input signal.

14. The method of claim 13, wherein the digital-to-analog converter converts the digital input signal at a conversion rate that is an integer multiple of a frequency of the digital periodic input signal.

15. The method of claim 14, wherein the digitizing includes digitizing in an analog-to-digital converter at a conversion rate that is the conversion rate of the analog-to-digital converter, divided by an integer that is different from the integer multiple.

16. The method of claim 14, wherein the digitizing includes digitizing in an analog-to-digital converter at a conversion rate that less that the conversion rate of the analog-to-digital converter.

17. The method of claim 13, wherein the using the phase and/or the amplitude of the digitized output signals also includes using calibration data.

18. The method of claim 13, further comprising applying a Fourier transform on the digitized output signals to determine the phase and/or the amplitude of the digitized output signals.

19. The method of claim 13, further comprising applying an aliasing algorithm on the digitized output signals to determine the phase and/or the amplitude of the digitized output signals.
